(19) United States
(12) Patent Application Publication
(10) Pub. No.: US 2009/0268762 A1
(43) Pub. Date: Oct. 29, 2009

(54) Optical intergrated device

(76) Inventors: Jan De Merlier, Tokyo (JP); Kenji Sato, Tokyo (JP); Kenji Mizutani, Tokyo (JP); Koii Kudo, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(21) Appl. No.: 11/921,763

(22) PCT Filed: Jun. 8, 2005
(86) PCT No.: PCT/JP2005/010903

§ 371 Date: Dec. 30, 2008

(51) Int. Cl. H01S 3/10; H01S 3/08; H01S 5/00

(52) U.S. Cl. 372/20; 372/99; 372/49.01

(57) ABSTRACT

An object of the invention is to provide an optical integrated device which enables to supply a wide range of variable wavelength and to reduce the coupling loss. The optical integrated circuit chip (10) includes a semiconductor optical amplifier section (20), a phase control section (18), a partially reflecting mirror (16) having optical power splitter function and a Mach-Zehnder optical modulator (22), wherein all elements are formed on a same substrate monolithically. On each facet of the optical integrated circuit chip (10), an Anti-Reflection coating (12, 14) is formed respectively. A lens (30), an optical filter (32) and an external resonator mirror (28) are located outside of the optical integrated circuit chip (10), wherein an external cavity laser is formed with a semiconductor optical amplifier (SOA) section (20) operating as gain section, a partially reflecting mirror (16) operating as first reflecting mirror and an external resonator mirror (28) operating as a second mirror.

### TECHNICAL FIELD

This invention relates to an optical integrated device in which an external cavity laser and optical functional devices are integrated.

All of patents, patent applications, patent publications, scientific articles and the like, which will hereinafter be cited or identified in the present application, will, hereby, be incorporated by references in their entirety in order to describe more fully the state of the art, to which the present invention pertains.

### BACKGROUND ART

In Wavelength Division Multiplexed (WDM) optical networks different optical carriers, each digitally modulated by data streams, are combined and propagated through one optical fiber. The wavelengths of these carriers are determined by the International Telephone Union (ITU) standard wavelengths. In the future, wavelength tunable laser sources able to address a large number of ITU channels will be required as this will allow for dynamic reconfiguration in optical networks. One of the light sources which meet such a requirement, an external cavity laser with tunable wavelength is disclosed in the Japanese laid-open patent publication No. 10-223991. The tunable wavelength laser comprises a laser diode and an external reflector to form an external resonator and can provide a wide tuning range of the lasing wavelength by changing the wavelength selection through a wavelength selector element such as a band-pass filter inserted into the resonator during the oscillation.

FIG. 5 shows a configuration of a conventional variable wavelength laser device with an external resonator. A low reflection film 68b is provided on one facet of the gain medium 68a and a non-reflection film 68c is provided on the other facet of the gain medium 68a. The light emitted from the laser diode 68 is converted to parallel rays through the lens 69b. A mirror 63 is provided after the lens 69b and a variable optical band-pass filter 62 is placed between the lens 69b and the mirror 63. Therefore an external resonator is formed between the mirror 63 and the low reflection film 68b. Furthermore, another lens 69a is provided after the low reflection film 68b of the laser diode 68, so that the laser beam transmitted through the lens 69a is output from the output port 61 via the optical fiber 60.

In addition, integration and minimization of elements such as laser diode light sources which allow tuning of the lasing wavelength, optical modulators, optical amplifiers and optical wavelength filters is required for WDM optical communication networks.

FIG. 6 schematically shows a hybrid integration of a laser diode and an optical modulator. The optical output of the laser diode is collimated by a first lens and the collimated laser beam is again converged by a second lens input to the facet of the optical modulator. In this case, the coupling loss between the laser diode and the modulator could be over 10 dB. Therefore, a high power output from the laser diode of the first stage is required in order to have sufficient power after the modulator. Furthermore this approach complicates the packaging significantly and results in bulky devices.

A way to reduce the coupling loss is to integrate e.g. an optical modulator with the gain medium of an external cavity laser on the same substrate as is disclosed in U.S. Pat. No. 6,295,308. In this patent several ways to achieve the integration by adding a partially reflecting mirror between the gain section and the optical modulator are proposed namely an etched facet, a loop mirror and a Distributed Bragg Reflector (DBR). However the etched facet will create a Fabry-Perot cavity with the input facet of the modulator and will result in a wavelength dependent reflectivity. The loop mirror requires a large area on the semiconductor chip and the DBR is inherently limited in bandwidth. Therefore these solutions are not practical for use in an external cavity wavelength tunable laser.
Better methods for the integration of a wavelength tunable external cavity laser with other optical functions are required.

### DISCLOSURE OF INVENTION

It is therefore an object of the invention to provide an optical integrated device formed by integration of a semiconductor laser element and optical function elements, which enables to reduce the size of the device, to provide a wide wavelength tuning range and to reduce the coupling loss between the optical elements.

The optical integrated device according to this invention comprises an optical integrated circuit chip including an optical function element section, an optical power splitter section, a first reflecting mirror and a gain section, which are all formed on a same substrate; a second reflecting mirror located outside of said optical integrated circuit chip to form a laser resonator together with said first reflecting mirror and said gain section; wherein said power splitter section is formed in said resonator on the optical integrated circuit chip, extracts light from the resonator and outputs the light to said optical function element section.

According to the invention a wide wavelength tuning range can be obtained by using an external cavity laser configuration in an optical integrated device comprising a semiconductor laser element and optical function elements. In addition, the gain section and the first reflecting mirror, which forms the external cavity laser device, and the optical function elements and the optical power splitter section, are all provided on a same substrate monolithically. Thereby a higher integration and the functionality of the optical integrated device will be achieved and the coupling loss between the optical elements will be reduced. Furthermore, the laser light can be divided with a small coupling loss by providing the optical power splitter section in the laser resonator formed on the substrate.

According to the invention, a small sized optical integrated device can be provided, which enables to supply a wide range of variable wavelength and to reduce the coupling loss.

### BRIEF DESCRIPTION OF DRAWINGS

FIG. 1 is a schematic diagram of an optical integrated device in accordance with first embodiment of the invention.

FIG. 2 schematically shows an alternative configuration of the looped mirror used in the embodiment of FIG. 1.

FIG. 3 is a schematic diagram of an optical integrated device in accordance with second embodiment of the invention.

FIG. 4 is a schematic overview showing an alternative configuration of the optical integrated device in accordance with second embodiment of the invention.

FIG. 5 is a schematic diagram of a conventional semiconductor external cavity laser device.

FIG. 6 schematically shows a conventional optical coupling by which a laser diode and an optical modulator are integrated.

### BEST MODE FOR CARRYING OUT THE INVENTION

This invention realizes an object to provide an optical integrated device which enables to supply a wide wavelength tuning range and to reduce the coupling loss to other optical functional elements.

### EXAMPLES

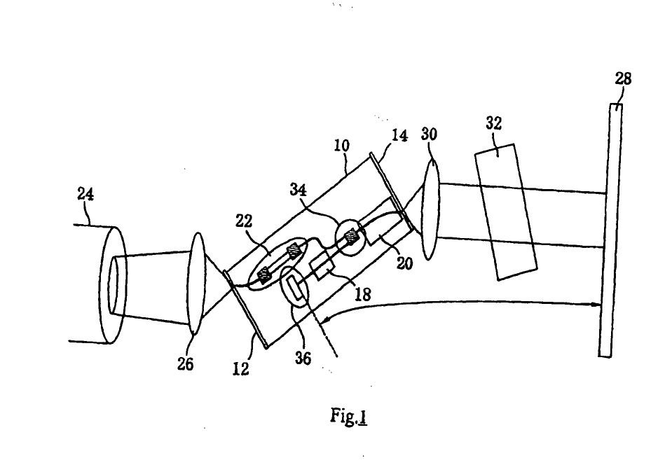

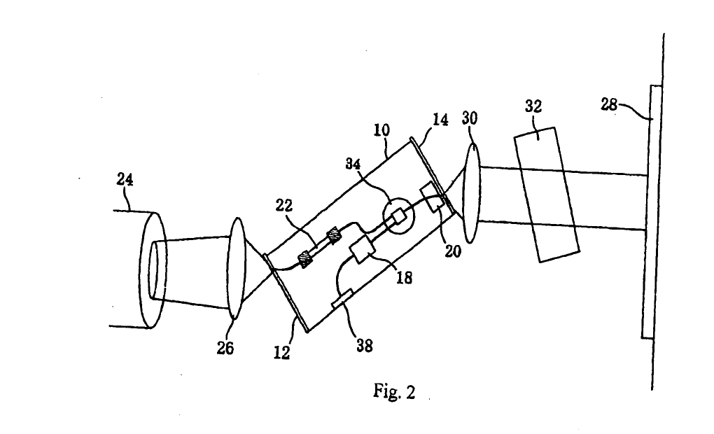

A first embodiment of the invention will be described with reference to the FIG. 1-2.

FIG. 1 is an overview showing a configuration of an optical integrated circuit in accordance with a first embodiment of the invention. As shown in FIG. 1, an optical integrated circuit chip 10 includes a semiconductor optical amplifier section 20, a phase control section 18, a partially reflecting mirror element consisting of an optical power splitter 15 and a reflection element 16 and a Mach-Zehnder optical modulator 22, wherein all elements are formed on a same substrate monolithically. On each facet of the optical integrated circuit chip 10, an Anti-Reflection coating 12, 14 is formed respectively.

Furthermore, a lens 30, an optical filter 32 and an external resonator mirror 28 are located outside of the optical integrated circuit chip 10, wherein an external cavity laser is formed with a semiconductor optical amplifier (SOA) section 20 operating as gain section, a partially reflecting mirror 16 operating as first reflecting mirror and an external resonator mirror 28 operating as a second mirror.

The external resonator mirror 28 is formed by coating a plate with a multilayer reflection film. In this embodiment, the optical filter 32 comprises a tunable etalon and enables to select a suitable wavelength through a change in the refractive index of the etalon, resulting in a wavelength shift of the transmission peak. Depending on the etalon layout, this can be achieved through a change in e.g. temperature or voltage. The optical amplifier section 20 is located between the phase control section 18 and the AR coated facet facing the external cavity 14. By feeding current into the phase control section 18, its effective refractivity is changed and thereby the oscillation wavelength can be adjusted accurately.

According to the first embodiment of the invention, as shown in FIG. 1, a Mach-Zehnder optical modulator 22 is used as an optical function element. The output light from the partially reflecting mirror 16 is modulated in the Mach-Zehnder optical modulator 22 and thereafter emitted via the facet of the optical integrated circuit chip into the optical fiber 24.

The active and passive waveguides provided on the optical integrated circuit are preferably formed onto a substrate monolithically. FIG. 2 schematically shows the operation of the partially reflecting mirror 16 used in the first embodiment of the FIG. 1. In this configuration, light from the lasing cavity is coupled into a first input port of a directional coupler. Light is coupled to the neighboring waveguide through evanescent coupling. At the end of the directional coupler the light is reflected at an etched facet and the reflected light is going back through the directional coupler. After propagation through the directional coupler, part of the light will be coupled back to the lasing cavity, another part is sent to the output port leading to the Mach-Zehnder modulator located outside of the lasing cavity. The reflecting portion can be formed with any material and configuration that can reflect the light beam from the amplifier section. For instance, the reflecting portion can be formed with a metal coating such as Gold (Au), a multilayer reflection film which is formed with multiple layers each having different refractivity laminated together, or a diffraction grating comprising an air gap. The location of the reflecting portion is not limited to the upper side of the substrate; it can be formed at the flank of the optical integrated circuit by extending the directional coupler to the flank of the chip.

Although the optical power splitter section is formed using a directional coupler in the first embodiment, it is not limited to this configuration. For example, it can be formed using a 2×2 MMI (multimode interference) waveguide. In the case of a directional coupler, the transmission and reflection of the partially reflecting mirror is determined by the power splitting ratio of the coupler x/1−x and the power reflectivity of the reflecting section R₁. The total power transmission T and power reflection R equals:

T=4×(1−x)R₁

R=(2x−1)²R₁

Although a Mach-Zehnder modulator is used as an optical function element in the first embodiment, it is also not limited to this configuration. For example, an electro-absorption modulator or a variable optical attenuator can be used.

Although a transmission type filter, in this specific case an etalon, is located between the optical integrated circuit chip and the external resonator mirror 28 to form an optical filter, this can be substituted by providing a reflection type wavelength selector element on the surface of the external resonator mirror 28. For example an external resonator mirror having a grating formed on its surface can be used so that it can operate to select a required wavelength and also as an external resonator mirror.

The production process of the optical integrated circuit chip of the first embodiment will be described below. An InGaAsP/InP double hetero structure comprising a MQW structure with a bandgap wavelength of 1.58 μm is laminated onto an InP substrate. Thereafter, a portion for forming the passive and phase sections 20 is cut out and then an optical waveguide core layer with a bandgap of 1.3 μm is formed in the cutout portion. Further, the construction is treated to a required waveguide form by mesa etching and then mesa type waveguides are embedded by embedding layers. The waveguides leading to the AR coated facets 12 and 14 of the chip are preferably tilted such that the facets of the waveguides are not vertical to the reflected light from the external resonator mirror 28, thereby the effect of the feed back light on the facet during the light input/output to the optical integrated circuit chip can be reduced. For example, the tilt can amount approximately 7 to 10 degree. Finally, the optical integrated circuit chip is completed by etching to separate the elements and by forming the electrodes on the active waveguide sections.

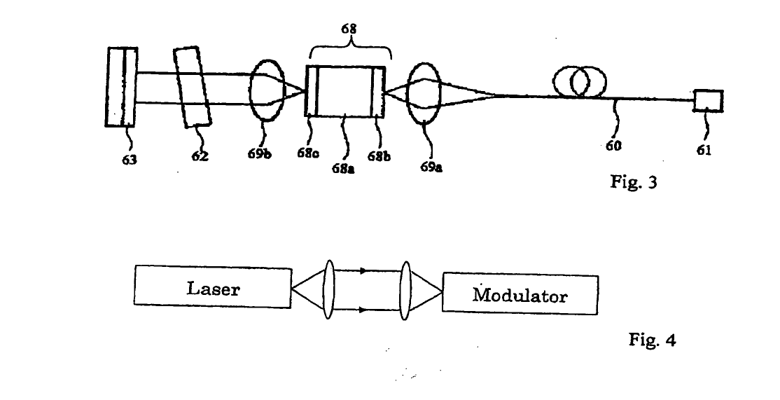

A second embodiment of the invention will be now described with reference to the FIG. 3.

FIG. 3 shows an overview of an optical integrated device in accordance with second embodiment of the invention. As shown in FIG. 3, an optical integrated circuit chip 10 includes a semiconductor optical amplifier section 20, an optical power splitter section 34, a phase control section 18, a reflecting section 36 and a Mach-Zehnder optical modulator 22, wherein all of said elements are formed on a same substrate monolithically. On the in- and output facets of the optical integrated circuit chip 10, an AR-coating (Anti-Reflection coating) 12, 14 is formed respectively.

A lens 30, an optical filter 32 and an external resonator mirror 28 are located outside of the optical integrated circuit chip 10. An external cavity laser is formed with the semiconductor optical amplifier (SOA) section 20 operating as gain section, the reflecting section 36 operating as a first reflecting mirror and the external resonator mirror 28 operating as a second mirror. The configurations of the external resonator mirror 28, the optical filter 32 and the lens 30 are identical to those of the first embodiment and therefore detailed description can be omitted.

As an optical power splitter section for extracting optical output power from the external resonator, a 1×2 multi-mode interference waveguide 34 is located between the reflecting section 36 and the optical amplifier section 20. The power is divided and one part is guided to the optical modulator. The other part is guided to a reflecting section to provide the feedback which is required to form a cavity. Other than the 1×2 multi-mode interference waveguide, a 2×2 multi-mode interference waveguide, a Y-branch waveguide or a directional coupler can be used as optical power splitter section.

The phase control section 18 is located between the reflecting section 36 and the optical power splitter section 20, and is used for fine tuning of the oscillation wavelength by changing its effective refractivity through the current fed thereto.

In case that the reflecting section 36 is provided in the optical integrated circuit chip, a space can be formed by etching in which a metal coating such as Gold(AU) is provided, or a air gap or a grating can be formed by etching in the chip, which enables to reflect the light beam.

FIG. 4 shows an alternative configuration of the second embodiment of the invention. As shown in FIG. 4, the location of the reflecting section is not limited to inner area of the chip; a configuration is also possible in which a bending waveguide is extended to the flank of the optical integrated circuit chip and a high reflection coating 38 is formed in the area adjacent to the flank.

The active and passive waveguides provided on the optical integrated circuit are preferably formed onto a substrate monolithically.

### INDUSTRIAL APPLICABILITY

As follows, optical integrated circuit according to the invention is useful in telecommunication applications, in particular, as a signal source for optical networks.

1. An optical integrated device comprising:
a first reflecting mirror;
provided in an optical integrated circuit chip;
a second reflecting mirror provided outside of the optical integrated circuit chip and configured to form a laser resonator with the first reflecting mirror; and
an optical power splitter provided on a path of a resonating laser light of the laser resonator, in the optical integrated circuit chip.

2. An optical integrated device according to claim 1, wherein the optical power splitter comprises a 1×2 multi-mode interference waveguide, a 2×2 multi mode interference waveguide, a Y-branch waveguide or a directional coupler.

3. An optical integrated device according to claim 1, wherein the first reflecting mirror comprises an etched facet.

4. An optical integrated device according to claim 1, wherein the first reflecting mirror comprises a cleaved facet.

5. An optical integrated device according to claim 1, wherein the optical integrated circuit chip further comprises titled waveguides that lead light to facets of the optical integrated circuit chip.

6. An optical integrated device according to claim 1, wherein the optical integrated circuit chip further comprises anti-reflection coated facets.

7. (canceled)

8. An optical integrated device according to claim 1, further comprising a phase control section provided between the first reflecting mirror and the optical power splitter.

9. An optical integrated device according to claim 1, further comprising an optical filter provided in front of the second reflecting mirror.

10. An optical integrated device according to claim 9, wherein the optical filter or the second reflecting mirror includes a tunable filter function.

11. An optical integrated device according to claim 9, wherein the optical filter comprises a tunable etalon.

12. (canceled)

13. (canceled)

14. An optical integrated device according to claim 1, further comprising an optical function element, wherein the optical power splitter is optically connected to the optical function element.

15. An optical integrated device according to claim 14, wherein the optical function element comprises at least one of a Mach-Zehnder modulator, an electro-absorption modulator and a variable optical attenuator.

16. An optical integrated device according to claim 3, wherein the first reflecting mirror comprises an etched facet with metal coating, grating or multi-layer reflection film.

17. An optical integrated device according to claim 4, wherein the first reflecting mirror comprises a cleaved facet with metal coating or a multi-layer reflection film.

18. A method, comprising:
resonating light between inside of a semiconductor chip and outside of the semiconductor chip;
splitting the resonating light; and
emitting the split light to the outside of the semiconductor chip.

19. A method according to claim 18, further comprising controlling the emitted light.
